(19) United States
(12) Patent Application Publication
(10) Pub. No.: US 2016/0276879 A1
(43) Pub. Date: Sep. 22, 2016

(54) Nanoscale Magnet Composite for High-Performance Permanent Magnets

(71) Applicant: SIEMENS AKTIENGESELLSCHAFT, Muenchen (DE)

(72) Inventors: Caroline Cassignol, Muenchen (DE); Michael Krispin, Vaterstetten (DE); Inga Zins, Muenchen (DE)

(73) Assignee: Siemens Aktiengesellschaft, Muenchen (DE)

(21) Appl. No.: 15/031,309

(22) PCT Filed: Aug. 19, 2014
(86) PCT No.: PCT/EP2014/067619

§ 371 Date: Apr. 22, 2016

(30) Foreign Application Priority Data
Oct. 28, 2013 (DE) 10 2013 221 828.1

(51) Int. Cl. H02K 1/02; C23C 16/44; C23C 14/22; H01F 7/02

(52) U.S. Cl. CPC H02K 1/02; H01F 7/02; C23C 16/44; C23C 14/22

(57) ABSTRACT

A nanoparticle is disclosed that has an elongated core extending from a first end to a second end along a longitudinal axis and formed of at least one magnetizable and/or magnetized material. A first cover is formed on a first end of the core, and a second cover is formed on a second end of the core, the first cover and the second cover formed from a magnetocrystalline anisotropic material different than the material of the core. The core is uncovered by the first and second covers along a non-zero longitudinal distance between the first and second covers. In this way, the material of the covers can be reduced in relation to the generated coercive force, which may allow for efficient and reduced-cost permanent magnets.

### CROSS-REFERENCE TO RELATED APPLICATIONS

This application is a U.S. National Stage Application of International Application No. PCT/EP2014/067619 filed Aug. 19, 2014, which designates the United States of America, and claims priority to DE application No. 10 2013 221 828.1 filed Oct. 28, 2013, the contents of which are hereby incorporated by reference in their entirety.

### TECHNICAL FIELD

The invention relates to nanoparticles for use in permanent magnets, for example in electric motors or generators.

### BACKGROUND

Permanently energized motors and generators present great demands on the magnetic properties of the permanent magnets used. In a conventional construction, these are achieved merely with anisotropic sintered rare earth magnetic materials based on neodymium-iron-boron or samarium-cobalt. The reduction in access to rare earth elements has led to an intensification of the search for new permanently magnetic, in particular rare earth-free, magnetic materials. This has been stimulated in particular by nanotechnology. This is due to the fact that permanent magnetic properties, in addition to the high magnetization (magnetic polarization) due to a suitable atomic and crystallographic structure, are greatly dependent on magnetization processes at the mesoscopic scale. Permanent magnetic properties are promoted by the micro-structural construction as nanoscale single-domain particles, as known in the context of the rapid-solidification technique.

However, the synthetic construction of permanent magnetic materials made of nanoparticles having high spontaneous magnetization is prevented by the increasing sensitivity to oxidation in nanoparticles. Thus, even favored transition metal alloys of Co and Fe are easily oxidized.

The coercive field strengths which can be achieved by what is referred to as shape anisotropy cannot be achieved experimentally at the same time.

While, in current rare earth-based permanent magnets (e.g. SmCo or NdFeB), high magnetocrystalline anisotropy in microcrystalline, metallurgically produced microstructures generates a coercive field strength which is sufficiently strong for almost all current applications, the remanent magnetization in these systems remains limited to the spontaneous magnetization of the magnetically hard phase (e.g. Nd₂Fe₁₄B of 1.61 T).

Nanotechnological synthesis methods can be used, by virtue of the shaping possibility, to produce magnetically single-domain nanoparticles. The nanoparticles can also take the form of elongate ellipsoids, nanowires or nanorods and can be arranged in oriented ensembles. Ferromagnetic materials such as NiFe and CoFe, originally known as magnetically soft metals and alloys, are used on account of the shape anisotropy to create a permanently magnetic material having substantial magnetic reversal stability. In that context, the anisotropy field as an upper limit for the coercive field is limited, for infinitely elongate particle geometries, to 2Pi*Ms (saturation magnetization). Due to influences from the ensemble, but also on account of the fact that the coercive field is reduced by defects on the surface of the nanoparticles and by corners and edges (μH=alpha*μHa−Neff*Js), it has not been clear to date whether this limit value can be achieved in the ensemble of particles, or whether additionally other magnetic reversal modes (curling, fanning) emerge that likewise result in a reduced coercive field.

A common maximum value for a coercive field in FeCo nanowires is approximately 5.5 kOe and is thus too low for high energy densities. This can once again be remedied conventionally by means of what is termed the core-shell method, that is to say depositing a second magnetically hard material onto the outer surface of the shape-anisotropic nanoparticle. A magnetically hard shell can then be deposited areally onto the nanoparticle and can completely cover the nanoparticle. DE 10 2012 204 083.8 discloses such an arrangement.

DE 10 2012 204 083.8 discloses a nanoparticle having at least one elongate core which is formed with at least one first, magnetizable and/or magnetized material and with a shell, surrounding the core, which is formed with at least one second material having magnetocrystalline anisotropy.

This concept of two-phase magnets, referred to as exchange spring magnets, has been investigated in metallurgical methods—in particular what is called the rapid quenching process. However, limited control with respect to shaping and distribution of the two phases with respect one another leads to a sharp drop in the coercive field strength and thus to reduced permanent magnetic properties.

### SUMMARY

One embodiment provides nanoparticles, having an elongate core extending from a first end to a second end along a longitudinal axis, which core is made using at least one first, magnetizable and/or magnetized material; wherein, on the core, a first covering is formed at the first end and a second covering is formed at the second end, which coverings have a second material having magnetocrystalline anisotropy, wherein the core is not covered thereby between the first covering and the second covering over a distance greater than zero along the longitudinal axis.

In a further embodiment, the first covering and the second covering cover surface regions of the core that extend transversely with respect to the longitudinal axis.

In a further embodiment, the first covering and the second covering completely cover the surface regions of the core that extend transversely with respect to the longitudinal axis.

In a further embodiment, the first covering and the second covering cover surface regions of the core that extend along the longitudinal axis.

In a further embodiment, the first covering entirely coats the first end and the second covering entirely coats the second end.

In a further embodiment, the second material consists of second nanoparticles whose volumes are in each case smaller than that of the core.

In a further embodiment, the volume of the second nanoparticles is 1 to 20% of the volume of the core.

In a further embodiment, the second nanoparticles are spherical.

In a further embodiment, the distance between the first covering and the second covering is at least 50%, in particular 80%, of the length of the core along the longitudinal axis.

In a further embodiment, the nanoparticle is formed as a nanorod and the core is cylindrical with a length and a radius.

In a further embodiment, the first covering and the second covering are in each case in the form of a cylinder, a hollow cylinder, a hollow cylinder having a base cylinder, or a pebble bed.

In a further embodiment, the first covering and the second covering have a thickness.

In a further embodiment, the distance is the length of the core plus twice the thickness and minus the extent of the first covering and of the second covering along the longitudinal axis.

In a further embodiment, an outer protective layer for protection from corrosion, in particular oxidation, is formed.

In a further embodiment, the first covering and the second covering form part of the protective layer.

Another embodiment provides a method for coating a nanoparticle with a first covering and a second covering as disclosed above, wherein the core on one hand and the first covering and the second covering on the other hand are synthesized separately from one another and subsequently chemical or physical deposition of the second material onto the first material is carried out.

Another embodiment provides a permanent magnet comprising a multiplicity of nanoparticles as disclosed above.

In a further embodiment, the nanoparticles are arranged such that the orientations of the longest dimensions of the nanoparticles have a preferred direction.

Another embodiment provides an electric motor or generator having at least one permanent magnet as disclosed above, and a rotor (e.g., arranged radially inward from the at least one permanent magnet) configured to rotate relative to the at least one permanent magnet.

### BRIEF DESCRIPTION OF THE DRAWINGS

Example embodiments and aspects of the invention are described in more detail below with reference to the figures, in which:

FIG. 1 shows an example embodiment of a conventional nanoparticle;

FIG. 2 shows a first example embodiment of an inventive nanoparticle;

FIG. 3 shows a second example embodiment of an inventive nanoparticle;

FIG. 4 shows a third example embodiment of an inventive nanoparticle;

FIG. 5 shows an example embodiment of an inventive method for producing nanoparticles;

FIG. 6 shows an example embodiment of an inventive application.

### DETAILED DESCRIPTION

Embodiments of the invention provide an improved nanoparticle. For example, the nanoparticle may be used to create an improved permanently magnetic material. Other embodiments provide an improved permanent magnet and an improved electric motor and an improved generator. New concepts for synthetic permanent magnets are also disclosed. An effective increase in the energy density may be achieved. Sensitivity to oxidation may be reduced and achievable coercive field strengths may be increased.

Some embodiments provide a nanoparticle having an elongate core extending from a first end to a second end along a longitudinal axis, which core is made using at least one first, magnetizable and/or magnetized material, wherein, on the core, a first covering is formed at the first end and a second covering is formed at the second end, which coverings have a second material having magnetocrystalline anisotropy, wherein the core is not covered thereby between the first covering and the second covering over a distance >0 along the longitudinal axis.

In that context, and within the meaning of this invention, a nanoparticle is to be understood as a particle having a diameter of less than 1000 nm. In particular, the nanoparticle has a diameter of less than 300 nm.

An elongate core is to be understood, within the meaning of this invention, as a core having an aspect ratio—that is to say the ratio of the longitudinal dimension to the transverse dimension—of at least 1.5. The aspect ratio is suitably at least 5, ideally at least 10.

Elongated particles having a core-covering nanostructure, in which at least two material systems participate, may provide high permanent magnetic performance, e.g., high remanence, a high coercive field and a high energy product as well as to long-term stability; also disclosed is the combination of these magnet components to give ensembles.

One of the components, specifically the core phase, has a higher volume fraction and carries high magnetization.

A second phase, in this case the covering phase, has high magnetocrystalline anisotropy. This magnetically stabilizes the surface or the interface. In addition, the choice of core size, core diameter and covering thickness and optimized contact achieves a magnetic exchange coupling which leads to a single-phase magnetic reversal behavior and thus promotes homogeneous rotation in the case of high coercive fields.

It has been recognized, according to the invention, that the magnetic reversal process begins at the ends of the core phase or of the core. According to the invention, the second phase is deposited at the ends of the core phase. It has been recognized, according to the invention, that this permits an improvement in the magnetic properties while at the same time reducing the volume fraction of the second phase (the coating of the core) when compared to a closed phase.

The reduction of the total volume of the second phase, or of the second material, advantageously raises the magnetization of the nanoparticle when compared to complete encapsulation of the core. Reducing the fraction of the second phase advantageously reduces the price per magnet component since a large number of the materials used having high magnetocrystalline anisotropy are very expensive elements such as Pt, Pd or rare earths.

Other embodiments provide a method for coating a nanoparticle with a first covering and a second covering, wherein the core on one hand and the first covering and the second covering on the other hand are synthesized separately from one another and subsequently chemical or physical deposition of the second material onto the first material is carried out.

Further advantages arise in the synthesis of the magnet components in particular from the use of nanoparticles as the second phase or as the second material. Generally, homogeneous coating of a nanoparticle with a second layer is a great challenge, such that partial coating is advantageously simpler to carry out. Due to the magnetic interaction between the first and second phases, or between the first and second materials, it is advantageously favored to accumulate the second phase at the ends of the nanoparticles of the first phase. Synthesis can be carried out either in one step or separately. Separate synthesis makes it possible to use the optimum formation conditions for both phases. In many cases, and in particular for forming the hard phase, a thermal treatment may be required which exceeds the thermal stability of the first phase. For example, temperatures of approximately 1000° C. may be necessary for the formation of hard ferrites and temperatures above 600° C. may be required for converting FePt into the magnetically hard tetragonal structure. In addition, the conditions for forming the second phase can have a negative effect on the first phase, such as oxidation of the first phase. This can advantageously be prevented by means of separate synthesis. Deposition of the second phase can be carried out equally by means of chemical or physical methods.

By constructing according to the invention, a high coercive field is provided in a simple manner via the combination of high shape anisotropy with stabilization of the surface by magnetocrystalline anisotropy.

According to one embodiment, the first covering and the second covering can cover surface regions of the core that extend transversely with respect to the longitudinal axis.

According to another embodiment, the first covering and the second covering can completely cover the surface regions of the core that extend transversely with respect to the longitudinal axis.

According to another embodiment, the first covering and the second covering can cover surface regions of the core that extend along the longitudinal axis.

According to another embodiment, the first covering can entirely coat the first end and the second covering can entirely coat the second end.

According to another embodiment, the second material can consist of second nanoparticles whose volumes are in each case smaller than that of the core.

According to another embodiment, the total volume of the second nanoparticles can be 1 to 20% of the volume of the core.

According to another embodiment, the second nanoparticle can be spherical or the second nanoparticles can be spherical.

According to another embodiment, the distance between the first covering and the second covering can be at least 50%, in particular 80%, of the length of the core along the longitudinal axis.

According to another embodiment, the nanoparticle can be formed as a nanorod and the core can be cylindrical with a length and a radius.

According to another embodiment, the first covering and the second covering can in each case be in the form of a cylinder, a hollow cylinder, a hollow cylinder having a base cylinder, or a pebble bed.

According to another embodiment, the first covering and the second covering can have a thickness.

According to another embodiment, the distance can be the length of the core plus twice the thickness and minus the extent of the first covering and of the second covering along the longitudinal axis.

According to another embodiment, an outer protective layer for protection from corrosion, in particular oxidation, can be formed.

According to another embodiment, the first covering and the second covering can form part of the protective layer.

Other embodiments provide a permanent magnet comprising a multiplicity of the disclosed nanoparticles, wherein the nanoparticles are arranged such that the orientations of the longest dimensions along the longitudinal axis of the nanoparticles have a preferred direction.

According to another embodiment, permanent magnets according to the invention can be used in electric motors or generators.

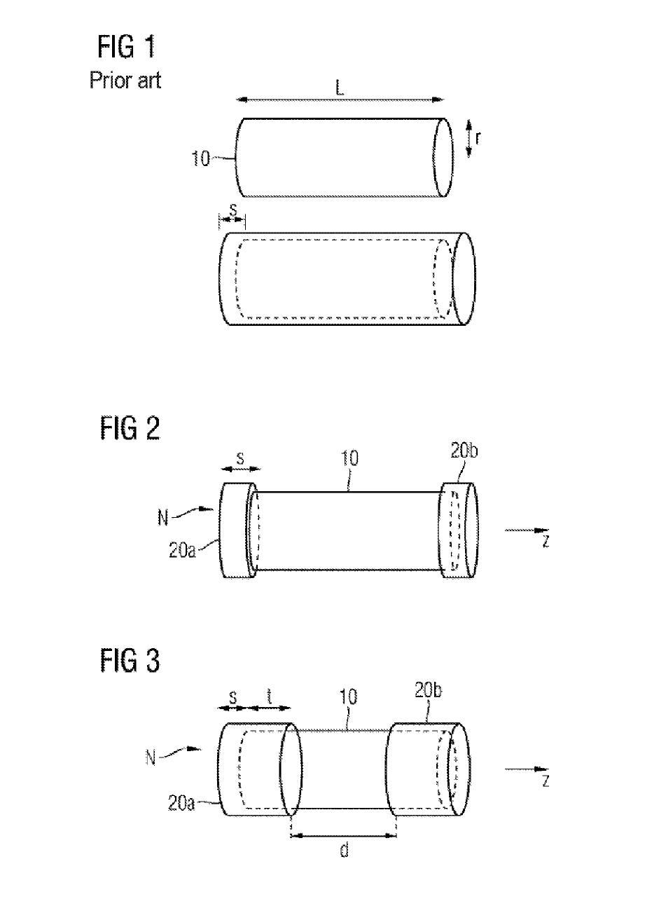

exampleexampleexampleexampleexampleexampleexample FIG. 1 shows an example of a conventional nanoparticle. FIG. 1 shows a conventional core-shell construction, wherein an elongate core 10 has a length L and a cylinder radius r. In this context, the magnetically hard shell is applied areally onto the core 10, the nanoparticle being completely covered. Such a construction can be termed a sarcophagus construction. The reference sign s represents the thickness of the shell.

FIG. 2 shows a first example embodiment of an inventive nanoparticle. The nanoparticle N is in this case in the form of a cylindrical nanorod. The elongate core 10 is cylindrical and extends along a longitudinal axis z from a left-hand end to a right-hand end. A first covering 20a covers a left-hand end face of a first end of the core 10. A second covering 20b covers a right-hand end face of a second end of the core 10. The reference sign s represents the thickness of a respective covering 20a or 20b. These thicknesses s are preferably equal. The coverings shown here can also be termed knobs. The first material of the core 10 can for example be transition metals, possibly FeCo with a high Fe fraction. The second phase or the second material can for example be FePt, MnBi, AlMnC or a hard ferrite. FIG. 2 shows that the nanoparticle N has an elongate core 10 which is only partially covered. The first material can advantageously be magnetically soft; the second material can advantageously be magnetically hard.

FIG. 2 shows a first example embodiment of an inventive nanoparticle. The first material, at least as volume material, may be magnetically soft. The first material may be formed with a ferromagnetic material, in particular Fe, e.g., with an alloy and/or a mixed crystal with Fe, e.g., NiFe or CoFe. The second material may be magnetically hard. The second material may be formed with a material having magnetocrystalline anisotropy, e.g., MnBi and/or MnAlC and/or FePt, e.g., by deposition of Pt onto Fe with subsequent heating. The nanoparticle can be designed as a nanorod and/or a nanowire. At least 60% of the volume fraction of the nanoparticle can be dispensed with on the core 10. It is also possible for an outer protective layer for protection from corrosion, in particular oxidation, to be formed. The first and second coverings 20a, 20b can form part of the protective layer. The protective layer may cover the entire circumference and preferably the entire surface area of the core 10 with the first and second coverings 20a, 20b. The protective layer can be formed with self-assembled monolayers (SAM). The protective layer can be formed with FePt, in particular by deposition of Pt onto Fe with subsequent heating.

FIG. 3 shows a second example embodiment of an inventive nanoparticle. In addition to the first covering 20a and the second covering 20b as shown in FIG. 2, surface regions of the core 10 that extend along the longitudinal axis are covered. The first covering 20a completely coats the first end and the second covering 20b completely coats the second end. The distance d defines the uncovered region of the core 10, wherein the distance d is the length L of the core 10 plus twice the thickness s and minus the spatial extent of the first covering 20a and of the second covering 20b along the longitudinal axis z. The magnetically hard coverings can, in that context, be applied areally onto the core 10, such that the nanoparticle N is once again partially covered.

Such coverings 20a and 20b can also be termed caps. In this case, the second phase takes the form of caps, and specifically the form of coverings of the end face and parts of the end face of the first phase. In comparison to the embodiment as shown in FIG. 2, the embodiment as shown in FIG. 3, with caps, leads to higher coercive fields.

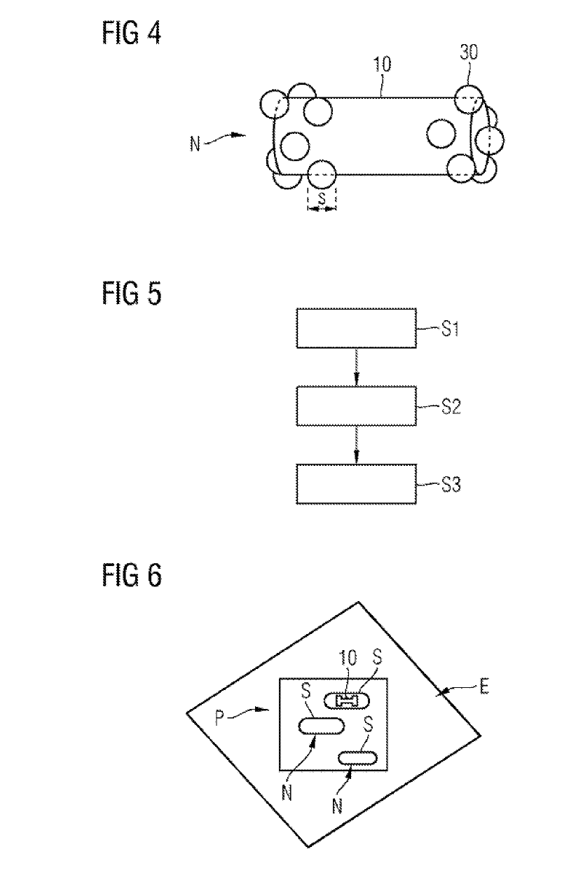

FIG. 4 shows a third example embodiment of an inventive nanoparticle. The nanoparticle N shown here has a first covering 20a and a second covering 20b which are in each case created from second nanoparticles 30 with or without shape anisotropy. The dimensions of these second nanoparticles 30 are significantly smaller than those of the elongate core 10 which is to be surrounded. If the first and second coverings 20a and 20b consist of such second nanoparticles 30, deposition of the second magnetic material onto the ends of the cores 10, which can be referred to as first nanoparticles, is advantageous. By means of nanotechnology, it is now possible to generate almost ideal magnet components. FIG. 4 shows that the second material, or the second phase, can also be applied or joined to the end faces, and to the side faces close to the end faces, in the form of nanoparticles 30. For just a small reduction in the coercive field in comparison to caps, the shell thickness of which corresponds to the diameter s of the nanoparticles of the second phase, the particles-on-core configuration permits a marked reduction in the total volume of the second phase or of the second material.

An example calculation using the following values r=10 nm, L=200 nm, s=2 nm and t=50 nm makes it advantageously possible to show the amount of second material saved by virtue of the invention. It has been shown that, for a so-called sarcophagus configuration as shown in FIG. 1, the coercive field strength of 250% in comparison to the core can be achieved with a volume fraction of the second phase of 47%. In the case of a cap arrangement according to the invention, as shown in FIG. 3, the coercive field strength can be raised to 172% in comparison to the core, while using of just 25% by volume of the second phase. In the embodiment according to FIG. 4, using nanoparticles, the coercive field strength can be brought to 120% in comparison to a pure core configuration, with the additional introduction of just 1% by volume. In other words, caps make it possible to achieve 69% of the coercive field strength of the sarcophagus while using just 53% of the volume of magnetically hard second material. Using inventive nanoparticles, in accordance with the third example embodiment, it is possible to achieve 48% of the coercive field strength of the sarcophagus while using just 2% of the volume of magnetically hard second material.

FIG. 5 shows an example embodiment of an inventive method for producing nanoparticles. In accordance with the method described here, the solution according to the invention is applied while using the second nanoparticles as second material. The elongate core 10 is generated in a first step. A second step S2 involves synthesis of the second material of the first and second coverings. A third step S3 involves chemical or physical deposition of the second material onto the first material. Examples for deposition of the second phase by chemical methods are in solution from a decomposition reaction, chemical gas phase deposition or spray pyrolysis. Examples of physical methods are laser ablation, ion beam-supported deposition, that is to say sputtering, and thermal spraying.

FIG. 6 shows an example embodiment of an inventive application. In an advantageous embodiment, the magnet components or inventive nanoparticles are surrounded with a protective shell S which is formed for example of carbon, silicon oxide or self-assembled monolayers. This protective shell S protects the inventive nanoparticle from corrosion and minimizes or prevents agglomeration of the nanoscale magnet components. Further, the inventive nanoparticles N can be oriented in a force field and can be brought together to form a macroscopic permanent magnet P. The nanoparticles described herein may be particularly well-suited to processing to give high-performance magnets which can for example be used in high-efficiency drives and generators.

The invention makes it possible to save second material with respect to the generated coercive field strength. It is accordingly possible to propose cost-saving solutions for permanent magnets.

What is claimed is:

1. A nanoparticle, comprising:
an elongate core extending from a first end to a second end along a longitudinal axis,
wherein the core comprises at least one first material that is magnetizable and/or magnetized;
a first covering formed at the first end of the core and
a second covering formed at the second end of the core,
wherein the first and second coverings comprise a second material having magnetocrystalline anisotropy, and
wherein a portion of the core between the first and second ends of the core, said portion extending a non-zero distance along the longitudinal axis, is not covered by the first or second covering.

2. The nanoparticle of claim 1, wherein the first covering and the second covering cover surface regions of the core that extend transversely with respect to the longitudinal axis.

3. The nanoparticle of claim 2, wherein the first covering and the second covering completely cover the surface regions of the core that extend transversely with respect to the longitudinal axis.

4. The nanoparticle of claim 1, wherein the first covering and the second covering cover surface regions of the core that extend along the longitudinal axis.

5. The nanoparticle of claim 4, wherein the first covering entirely coats the first end of the core and the second covering entirely coats the second end of the core.

6. The nanoparticle of claim 1, wherein the second material consists of second nanoparticles, each having a volume that is smaller than a volume of the core.

7. The nanoparticle of claim 6, wherein a total volume of the second nanoparticles is 1% to 20% of volume of the core.

8. The nanoparticle of claim 6, wherein the second nanoparticles are spherical.

9. The nanoparticle of claim 1, wherein a distance between the first covering and the second covering is at least 50% of a longitudinal length of the core.

10. The nanoparticle of claim 1, wherein the nanoparticle is formed as a nanorod and the core is cylindrical.

11. The nanoparticle of claim 10, wherein each of the first covering and the second covering have a cylindrical shape or a pebble bed shape.

12. (canceled)

13. The nanoparticle of claim 1, wherein the non-zero distance along the longitudinal axis of the core that is not covered by the first or second covering is equal to a total length of the core plus twice a thickness of the first covering plus a thickness of the second covering, minus respective longitudinal lengths of the core covered by either the first covering or the second covering.

14. The nanoparticle of claim 1, comprising an anti-oxidation outer protective layer formed around at least a portion of the core.

15. The nanoparticle of claim 14, wherein the first covering and the second covering form part of the anti-oxidation outer protective layer.

16. A method for forming and coating a nanoparticle, the method comprising:
synthesizing an elongated core;
synthesizing a first material separate from the synthesizing of the elongated core;
covering a first longitudinal end of the core with a first covering of the first material by chemical or physical deposition; and
covering a second longitudinal end of the core with a second covering of the first material by chemical or physical deposition.

17. A permanent magnet, comprising:
a plurality of nanoparticles, each comprising:
an elongate core extending from a first end to a second end along a longitudinal axis,
wherein the core comprises at least one first material that is magnetizable and/or magnetized;
a first covering formed at the first end of the core and
a second covering formed at the second end of the core,
wherein the first and second coverings comprise a second material having magnetocrystalline anisotropy, and
wherein a portion of the core between the first and second ends of the core, said portion extending a non-zero distance along the longitudinal axis, is not covered by the first or second covering.

18. The permanent magnet of claim 17, wherein the nanoparticles are arranged such that a longitudinal axis of the nanoparticles have a preferred direction of orientation.

19. An electric motor or generator, comprising:
at least one permanent magnet comprising:
a plurality of nanoparticles, each comprising:
an elongate core extending from a first end to a second end along a longitudinal axis,
wherein the core comprises at least one first material that is magnetizable and/or magnetized;
a first covering formed at the first end of the core and
a second covering formed at the second end of the core,
wherein the first and second coverings comprise a second material having magnetocrystalline anisotropy, and
wherein a portion of the core between the first and second ends of the core, said portion extending a non-zero distance along the longitudinal axis, is not covered by the first or second covering; and
a rotor configured to rotate relative to the at least one permanent magnet.
